(19) United States
(12) Patent Application Publication
(10) Pub. No.: US 2018/0180657 A1
(43) Pub. Date: Jun. 28, 2018

(54) TRANSFORMER CONDITION-BASED RISK MANAGEMENT SYSTEM AND METHOD

(71) Applicant: SANIL ELECTRIC CO., LTD., Ansan-si (KR)

(72) Inventors: Dong Suk PARK, Seoul (KR); Dong Zoon LEE, Yongin-si (KR)

(73) Assignee: SANIL ELECTRIC CO., LTD., Ansan-si (KR)

(21) Appl. No.: 15/798,409

(22) Filed: Oct. 31, 2017

(30) Foreign Application Priority Data
Dec. 23, 2016 (KR) 10-2016-0178208

(51) Int. Cl. G01R 31/02

(52) U.S. Cl. CPC G01R 31/027

(57) ABSTRACT

Disclosed is a transformer condition-based risk management system and method in which risk based on the condition of a transformer is managed using online real-time condition monitoring data, offline periodically measured data and design data reflected in design and is reflected in maintenance decision-making so that optimal asset management is carried out. The transformer condition-based risk management method includes measuring real-time condition monitoring data including temperature, dissolved gas and partial discharge data from a transformer online, periodic measurement data including insulating property data from the transformer offline, and historical data reflected in design of the transformer, assigning weights of corresponding assessment indexes according to technical, economic or social issues, to the respective measured data, receiving weighted data and then assigning delegation values to current measured values and measured value change estimated values, and summing respective data and then executing asset management through risk analysis of the transformer.

This application claims the benefit of Korean Patent Application No. 10-2016-0178208, filed on Dec. 23, 2016, which is hereby incorporated by reference as if fully set forth herein.

### BACKGROUND OF THE INVENTION

### Field of the Invention

The present invention relates to a transformer condition-based risk management system and method, and more particularly, to a transformer condition-based risk management system and method in which condition-based risk of a transformer of electric power equipment is managed to be reflected in maintenance decision-making so that optimal asset management is carried out.

### Discussion of the Related Art

In general, dependence on electricity in industrial enterprises or general homes is gradually increasing according to industrial development. Further, as electric power equipment is scaled up and densely concentrated and have multi-functions, when an electric accident occurs due to malfunction of electric power equipment, economic and industrial damages are enormous.

Particularly, in high-precision industries, such as the semiconductor industry, in which quality of electric power supplied to production facilities of industrial enterprises greatly influences performance or failure rate of manufactured products, even a small fault of electric power equipment may cause serious damage and thus high reliability electric power equipment is required.

However, a conventional maintenance method, in which maintenance is carried out according to a schedule regardless of the condition of electric power equipment, is ineffective in terms of costs and has many limits in facilities fault prevention.

Therefore, as an effective and economical maintenance method of electric power equipment, risk evaluation through operating history, diagnosis history, maintenance history, economic risk, etc. of electric power equipment and an integrated maintenance method and system through a substation asset management system including a risk evaluation system are spotlighted.

Conventionally, when electric power equipment is operated, a fixed weight is assigned to each of indexes and, thus, a periodic update function is provided. In this case, if various technical, economic and social issues occur, it is very difficult to reflect these issues.

Further, in order to manage assets of electric power equipment, various assessments, such as life assessment, condition assessment, risk assessment, etc., should be carried out first. For this purpose, the most important technical assessment is condition-based risk management.

However, since condition-based risk management has only a basic structure but methodology thereof is insufficient, it is difficult to execute condition-based risk management. Particularly, in a state in which online condition monitoring systems come into wide use, risk management methods using the same are not sufficiently developed now.

### PRIOR ART DOCUMENT

(Patent Document 1) Korean Patent Registration No. 10-0494642 (Registration Date: Jun. 1, 2005, Title: A diagnostic method for a dangerous condition of electrical power equipment using abnormal signals)

(Patent Document 2) Korean Patent Laid-open Publication No. 10-2014-0041568 (Publication Date: Apr. 4, 2014, Title: Method and system for estimating transformer remaining life)

### SUMMARY OF THE INVENTION

Accordingly, the present invention is directed to a transformer condition-based risk management system and method that substantially obviate one or more problems due to limitations and disadvantages of the related art.

An object of the present invention is to provide a transformer condition-based risk management system and method in which condition-based risk of a transformer is managed using online real-time condition monitoring data, offline periodically measured data and design data reflected in design and is reflected in maintenance decision-making so that optimal asset management is carried out.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a transformer condition-based risk management system includes an online data measurement unit configured to measure temperature, dissolved gas and partial discharge data from a transformer online, an offline data measurement unit configured to measure periodic measurement data including insulating property data from the transformer offline, a historical data measurement unit configured to measure historical data reflected in design of the transformer, an online data storage unit, an offline data storage unit and a historical data storage unit configured to receive and store online data, offline data and historical data measured by the online data measurement unit, the offline data measurement unit and the historical data measurement unit, an online data weighting unit, an offline weighting unit and a historical data weighting unit configured to assign weights of corresponding assessment indexes out of assessment indexes according to technical, economic or social issues, to the online data, the offline data and the historical data stored in the online data storage unit, the offline data storage unit and the historical data storage unit, an online data delegation unit, an offline data delegation unit and a historical data delegation unit configured to receive data, acquired by assigning the respective weights to the online data, the offline data and the historical data by the online data weighting unit, the offline data weighting unit and the historical data weighting unit, and then to assign delegation values to current measured values and measured value change estimated values, a data summing unit configured to sum online data, offline data and historical data transmitted from the online data delegation unit, the offline data delegation unit and the historical data delegation unit, and a risk management unit configured to receive result data, acquired by summing the online data, the offline data and the historical data by the data summing unit and to manage condition-based risk of the transformer using the result data.

In another aspect of the present invention, a transformer condition-based risk management method includes measuring real-time condition monitoring data including temperature, dissolved gas and partial discharge data from a transformer online, periodic measurement data including insulating property data from the transformer offline, and historical data reflected in design of the transformer, assigning weights of corresponding assessment indexes out of assessment indexes according to technical, economic or social issues, to the respective measured data, receiving weighted data and then assigning delegation values to current measured values and measured value change estimated value, and summing respective data, acquired by assigning the delegation values, and then executing asset management through risk analysis of the transformer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a block diagram schematically illustrating a transformer condition-based risk management system in accordance with the present invention; and

FIG. 2 is a flowchart illustrating a transformer condition-based risk management method in accordance with the present invention.

### DETAILED DESCRIPTION OF THE INVENTION

Reference will now be made in detail to the preferred embodiments of the present invention, examples of which are illustrated in the accompanying drawings. However, the disclosure of the invention is not limited to the embodiments set forth therein and may be variously modified. In the drawings, the same or similar elements are denoted by the same reference numerals even though they are depicted in different drawings.

In the following description of the embodiments, it will be understood that, when a part “includes” an element, the part may further include other elements, and does not exclude presence of the elements.

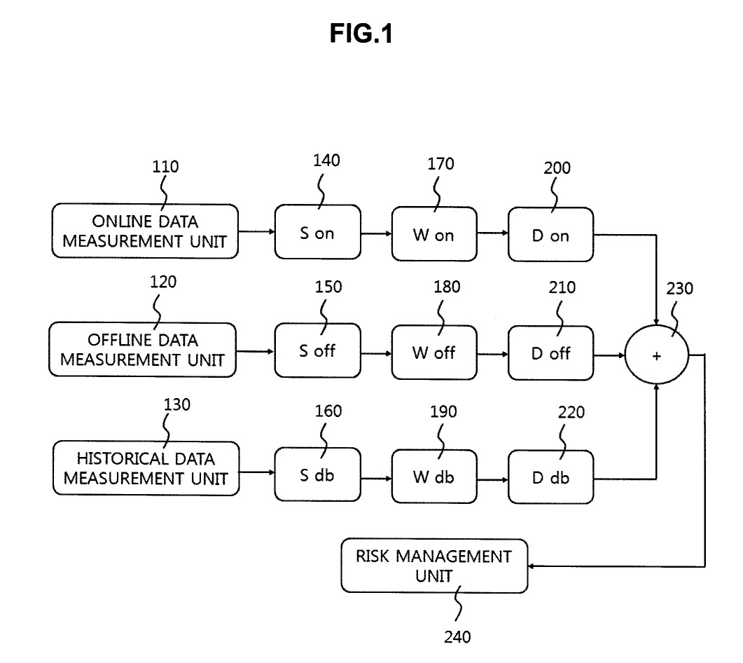

FIG. 1 is a block diagram schematically illustrating a transformer condition-based risk management system in accordance with the present invention.

The transformer condition-based risk management system in accordance with the present invention includes, as exemplarily shown in FIG. 1, an online data measurement unit 110 to measure temperature, dissolved gas and partial discharge data from a transformer online, an offline data measurement unit 120 to measure insulating property data from the transformer offline, a historical data measurement unit 130 to measure historical data reflected in design of the transformer, an online data storage unit 140, an offline data storage unit 150 and a historical data storage unit 160 to receive and store online data S on, offline data S off and historical data S db measured by the online data measurement unit 110, the offline data measurement unit 120 and the historical data measurement unit 130, an online data weighting unit 170, an offline weighting unit 180 and a historical data weighting unit 190 to assign weights of corresponding assessment indexes out of assessment indexes according to technical, economic or social issues, to the online data S on, the offline data S off and the historical data S db stored in the online data storage unit 140, the offline data storage unit 150 and the historical data storage unit 160, an online data delegation unit 200, an offline data delegation unit 210 and a historical data delegation unit 220 to receive weighted data W on, W off and W db from the online data weighting unit 170, the offline data weighting unit 180 and the historical data weighting unit 190, and then to assign delegation values to current measured values and measured value change estimated values, a data summing unit 230 to sum online data D on, offline data D off and historical data D db transmitted from the online data delegation unit 200, the offline data delegation unit 210 an the historical data delegation unit 220, and a risk management unit 240 to receive result data, acquired by summing the online data D on, the offline data D off and the historical data D db by the data summing unit 230, and to manage a degree of condition-based risk of the transformer using the result data.

Here, each of the online data measurement unit 110 and the offline data measurement unit 120 includes a plurality of sensor modules to measure various pieces of condition data of the transformer, and the sensor modules include a dissolved gas analysis sensor, a bushing monitoring sensor, a temperature sensor and a load current measurement sensor so as to construct representative tables of transformers.

Since transformers have different volumes, weights, overload resistances and temperature characteristics, degrees of influence of each of the sensor modules on the respective transformers are different. Therefore, degrees of influence of each sensor module on the respective transformers may be automatically determined according to transformer characteristics and operating situations through neutral network and artificial intelligence techniques using factory test data of the respective transformers.

Here, the online data measurement unit 110 monitors a condition of the transformer in real time online and separates temperature and gas data from various pieces of data acquired from the transformer.

Among issues used in the online data weighting unit 170, the offline data weighting unit 180 and the historical data weighting unit 190, technical issues may include, for example, detection of technical defects of a specific device, manufacturer, design or part, detection of abnormality during condition diagnosis, detection of failures, failure of a diagnostic system, etc.

Further, economic issues may include, for example, fluctuation in a price or stock level of a specific part, change in a maintenance policy or budget, fluctuation in power supply loss of a customer, etc.

Further, social issues may include, for example, environmental factors, safety factors, fault tolerance, external confidence, etc.

The fluctuation ranges of weights adjusted by the online data weighting unit 170, the offline data weighting unit 180 and the historical data weighting unit 190 are fixed, the maintenance periods of the respective adjusted weights are fixed, and, when the maintenance period of the adjusted weight passes, the adjusted weight returns to its original weight.

For example, if the weight of a hot-spot temperature, which is the most important factor to judge whether or not the transformer is abnormal, is set to 1, the weight of CO gas and the weight of C₂H₂ gas, which are relatively less important, are determined as 0.3 and 0.8 and, thus, importances of respective factors to be analyzed are automatically determined.

When a technical, economic or a social issue is input, the online data weighting unit 170, the offline data weighting unit 180 and the historical data weighting unit 190 temporarily adjust the weight of a corresponding assessment index out of the respective assessment indexes according to the input issue.

The online data delegation unit 200, the offline data delegation unit 210 and the historical data delegation unit 220 set the current measured values and the measured value change estimated values to be within the range of 0-2 and assign “1” to an online measured value, “2” to a measured value several months ago and a degradation estimated value and “0” to repaired/supplemented equipment as delegation values.

The risk management unit 240 assesses a degree of risk using the measured data of the transformer, the weights and the delegation values. In more detail, the risk management unit 240 calculates assessment indexes of assessment items, assigns corresponding weights to the respective calculated assessment indexes, and calculates an overall risk assessment index by collecting the assessment indexes, to which the weights are applied.

In such risk assessment, assessment indexes of the respective assessment items, including life assessment, condition assessment, integrity index assessment, economic risk assessment and social risk assessment of the transformer, may be calculated.

In the present invention, condition-based risk management (CBRM) data may be calculated by Equation 1 below.

$$C B R M = \frac{\sum ( S * W * D )}{\sum ( {S}_{max} * W * {D}_{2} )} \qquad [ Equation 1 ]$$

Here, S is an online or offline measured value level, which is within the range of 0-4. 0 indicates a level of safety, 1 indicates a level of interest, 2 indicates a level of attention, 3 indicates a level of warning, and 4 indicates a level of danger. W (Weight) is a weight of a measured factor, which is within in the range 1-20. D (Daily) is a current measured value or a measured value change estimated value, which is within the range of 0-2, 1 is assigned to an online measured value, 2 is assigned to a measured value several months ago and a degradation estimated value, and 0 is assigned to repaired/supplemented equipment.

The risk management unit 240 calculates a degree of condition-based risk of the transformer through the above-described measured levels, weights and delegation values.

The risk management unit 240 assesses a degree of risk of the transformer using data of electric power equipment from an asset database. Here, the risk management unit 240 calculates assessment indexes of respective assessment items, assigns corresponding weights to the respective calculated assessment indexes, and calculates an overall risk assessment index by collecting the assessment indexes, to which the weights are applied.

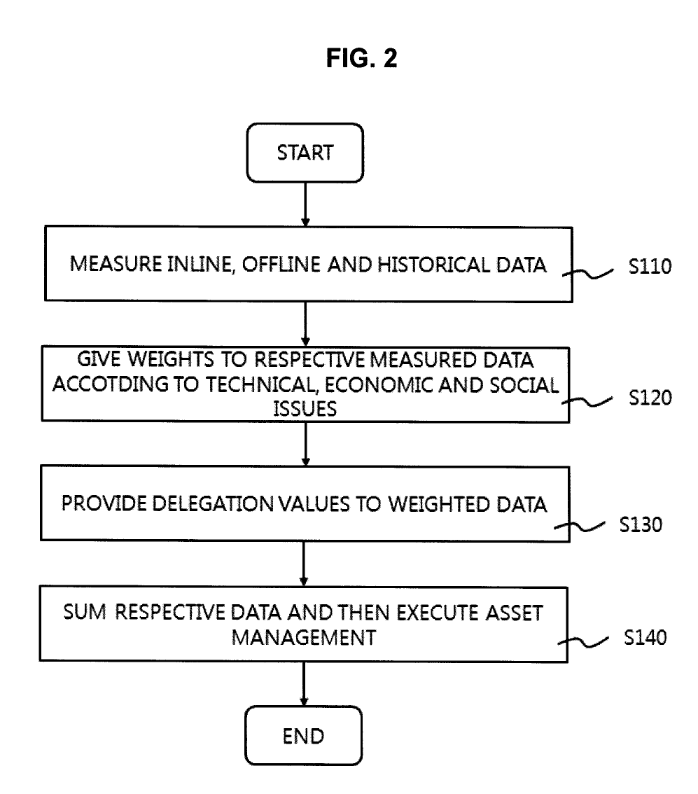

FIG. 2 is a flowchart illustrating a transformer condition-based risk management method in accordance with the present invention.

In the transformer condition-based risk management method, as exemplarily shown in FIG. 2, condition data of a transformer is measured online and offline and historical data reflected in design of the transformer is measured (Operation S110).

Here, the condition data of the transformer measured online and offline includes data regarding conditions of an insulating paper, coils, an iron core and insulating oil at the inside of the transformer, data regarding conditions of a tap changer, a bushing, a tank, a lightning arrester, a cooling pump and a cooling fan at the outside of the transformer, failure records including a record of surge invading the transformer and an accident record, and data regarding importance of the transformer according to whether or not a substation equipped with the transformer is a primary substation constituting the backbone of an electric power system or a substation for distribution.

The historical data, which is data regarding manufacture and design of the transformer, includes a manufacturer, rating, constants, frequency, whether or not the tap changer is present, a date of manufacture and test data in manufacturing of the transformer. Further, as the historical data, the diameter, height and width of the iron core of the transformer, and the coil rating, line-to-line voltage, line connection, rating current, coil BIL and coil structure of the coils are input. Moreover, as the historical data, information regarding the tap changer, such as the tap number, type and manufacturer of the tap changer, is input, and a kind of insulating oil, a cooling method, a tank size, etc. are input.

Here, weights of corresponding assessment indexes out of assessment indexes according to a technical, economic or social issue are assigned to the respective measured data (Operation S120).

Thereafter, weighted data is received and then delegation values are assigned to current measured values and measured value change estimated values (Operation S130).

Thereafter, respective data, acquired by assigning the delegation values, are summed and then asset management is executed through risk analysis of the transformer (Operation S140).

Here, risk of the transformer is generally assessed by divisionally assessing the inside of the transformer, the outside of the transformer, failure records and importance of the transformer according to the type of a substation. In assessment of the inside of the transformer, conditions of an insulating paper, coils, an iron core and insulating oil are assessed and, in assessment of the outside of the transformer, conditions of a tap changer, a bushing, a tank, a lightning arrester, a cooling pump and a cooling fan are assessed. Further, the failure records include a record of surge invading the transformer and an accident record, and the failure records are reflected in assessment of risk of the transformer. Further, importance of the transformer varies according to whether or not a substation equipped with the transformer is a primary substation constituting the backbone of an electric power system or a substation for distribution, i.e., according to importance of the substation, and importance of the transformer is reflected in assessment of risk of the transformer.

A method of assessing the inside of the transformer to assess risk of the transformer will be described below. Risk of the insulating paper is assessed by estimating residual life of the insulating paper through calculation of life loss of the insulating paper by a hot-spot temperature according to load, measuring tensile strength, an average degree of polymerization of the insulating paper and an amount of furfural and executing gas analysis. Risk of the coils is assessed using coil resistance, partial discharge, insulation resistance, impedance, exciting current, a power factor, FRA, a voltage ratio, IR, etc.

Risk of the iron core is assessed by measuring insulation resistance. Risk of the insulating oil is assessed using gas analysis, breakdown voltage, moisture, particles, interfacial tension, acidity, a power factor, a dielectric intensity, color, etc.

Further, a method of assessing the outside of the transformer to assess risk of the transformer will be described below. Risk of the tap changer is assessed using a degradation state of a tap changer contact point, an insulating oil test of OFU, etc. Risk of the bushing is assessed using a power factor, infrared thermography, capacitance, etc. Risk of the tank is assessed using a degree of corrosion, infrared thermography, etc. Risk of the lightning arrester is assessed using leakage current of arrester elements, condition of an insulating tube, etc. Risks of the cooling pump and the cooling fan are assessed using motor conditions of the cooling pump and the cooling fan.

Current conditions of the respective assessment items are expressed as 0-100%. Since influences of the respective assessment items on the life of the transformer are different, weights in the range of 0.1 to 1.0 are assigned to the respective assessment items according to influences of the respective assessment items on the life of the transformer, thus representing overall risk of the transformer. The condition of the transformer is assessed as normal, attention, abnormal, disposal or replacement, etc. according to total scores of the risk of the transformer.

When assessment of risk of the transformer has been completed, i.e., when assessment of overall risk of the transformer has been completed, measures corresponding to the risk of the transformer are taken. Assessment of risk of the transformer may be output as normal, attention, abnormal, disposal or replacement, etc., and proper measures corresponding to respective levels of risk may be taken.

Table 1 states assessment of risk of a transformer in accordance with one embodiment of the present invention. Here, a transformer, which has been operated for 25 years and in which conditions of a tank or other parts thereof are good but degradation of an insulating paper is considerably advanced due to overheating caused by overload, was exemplarily assessed. That is to say, in Table 1, assessment items include an insulating paper, coils, an iron core, insulating oil, a tap changer, a bushing, a tank, a lightning arrester, a cooling pump and a cooling fan, failure records, transformer importance, etc., current conditions of the respective assessment items are expressed as 0-100%, and weights in the range of 0.1 to 1.0 are assigned to the respective assessment items according to influences of the respective assessment items on the life of the transformer. Thereby, risks of the respective assessment items are calculated and then summed to acquire the overall degree of risk of the transformer.

TABLE 1

| | | Condition | Weight | |
|---|---|---|---|---|
| Assessment item | | (0~100%) | (0.1-1.0) | Risk |
| Inside of | Insulating paper | 55 | 0.8 | 44 |
| transformer | Coil | 10 | 0.8 | 8 |
| | Iron core | 10 | 0.8 | 8 |
| | Insulating oil | 20 | 0.1 | 2 |
| Outside of | Tap changer | 30 | 0.5 | 15 |
| transformer | Bushing | 10 | 0.5 | 5 |
| | Tank | 10 | 0.5 | 5 |
| | Lightning arrester | 10 | 0.5 | 5 |
| | Cooling pump and | 40 | 0.1 | 4 |
| | cooling fan | | | |
| Failure | Accident record and | 5 | 0.5 | 2.5 |
| records | surge record | | | |
| Importance | Primary substation | 5 | 0.5 | 2.7 |

| | |
|---|---|
| Total | 101.2 |

The transformer has been operated under the condition that an average load factor of 95% is applied thereto for 25 years and the maximum load factor of 110% is frequently applied thereto. Therefore, the hot-spot temperature of the transformer was 94° C. on average and was frequently increased to 120° C. at maximum. Therefore, a degradation accelerating element of life of a unit insulating paper was increased by 1.2 times and, thus, the insulating paper was degraded to 55% due to life loss and the insulating paper was degraded by 45% of a new product.

As such, risk of the insulating paper is assessed using transformer diagnosis and test data based on the life loss of the insulating paper. As a result of measurement of tensile strength of the insulating paper to assess risk of the insulating paper, tensile strength of the insulating paper was lowered to 45% and the average degree of polymerization of the insulating paper was considerably lowered. As the transformer is operated at overload, a considerable amount of furfural generated due to degradation of the insulating paper was detected and, as a result of gas of insulating oil, large amounts of CO gas and CO₂ gas were generated.

To summarize such data, degradation of the insulating paper was progressed up to about 55%. Since influence of degradation of the insulating paper on risk of the transformer is considerably high, a weight of the insulating paper was set to 0.8. Therefore, a degree of risk of the insulating paper was 44.

In order to assess risk of the coils, whether or not partial discharge occurs in the coils or mechanical distortion of the coils is judged using coil resistance, partial discharge, insulation resistance, impedance, exciting current, a power factor, FRA, a voltage ratio, IR, etc. Whether or not partial discharge occurs in the coils is judged using data, such as gas analysis data, ultrasonic waves, UHF test data, etc. In the transformer in accordance with this embodiment, no partial discharge signal was detected. If partial discharge occurs in the coils, a large amount of C₂H₂ gas is detected through insulating oil analysis.

Further, if partial discharge occurs in the coils, the position of partial discharge is detected by measuring ultrasonic waves or UHF. Mechanical distortion of the coils is judged using SFRA data. In the transformer in accordance with this embodiment, SFRA data of the transformer did not indicate abnormality, and there was no mechanical distortion of the coils. To summarize such data, degradation of the coils was not progressed. Since influence of degradation of the coils on risk of the transformer is considerable high, a weight of the coils was set to 0.8. Therefore, a degree of risk of the coils was 8.

Risk of the iron core is assessed by measuring insulation resistance. In the transformer in accordance with this embodiment, insulation resistance was good and, thus, it was judged there is no change, such as dual-grounding of the iron core.

Risk of the insulating oil is assessed using gas analysis, breakdown voltage, moisture, particles, interfacial tension, acidity, a power factor, a dielectric intensity, color, etc. In the transformer in accordance with this embodiment, generation of large amounts of CO gas and CO₂ gas was detected through gas analysis of the insulating coil and an amount of moisture was increased. Therefore, it may be confirmed that, as the transformer has been operated at overload for 25 years, degradation of the insulating oil was more progressed than the coils or the iron core. However, since the insulating oil may be filtered or replaced with a new one and thus influence of degradation of the insulating oil on risk of the transformer is very low, a weight of the insulating oil was set to 0.1. Therefore, a degree of risk of the insulating paper was 2.

Thereafter, the outside of the transformer, failure records and importance of the transformer are assessed through the above-described method and, thus, a transformer risk assessment table including the items stated in Table 1 is made and the overall degree of risk of the transformer is assessed. In the above-described transformer which has been operated for 25 years, the insulating paper was degraded to 55% due to overheating caused by overload and the tap changer was degraded to 30%.

Therefore, the total risk score of the transformer is expressed as 101.2 and, thus, the transformer was assessed as being disposed or replaced.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A transformer condition-based risk management system comprising:
an online data measurement unit configured to measure real-time condition monitoring data including temperature, dissolved gas and partial discharge data from a transformer online;
an offline data measurement unit configured to measure periodic measurement data including insulating property data from the transformer offline;
a historical data measurement unit configured to measure historical data reflected in design of the transformer;
an online data storage unit, an offline data storage unit and a historical data storage unit configured to receive and store online data, offline data and historical data measured by the online data measurement unit, the offline data measurement unit and the historical data measurement unit;
an online data weighting unit, an offline weighting unit and a historical data weighting unit configured to assign weights of corresponding assessment indexes out of assessment indexes according to technical, economic or social issues, to the online data, the offline data and the historical data stored in the online data storage unit, the offline data storage unit and the historical data storage unit;
an online data delegation unit, an offline data delegation unit and a historical data delegation unit configured to receive data, acquired by assigning the respective weights to the online data, the offline data and the historical data by the online data weighting unit, the offline data weighting unit and the historical data weighting unit, and then to assign delegation values to current measured values and measured value change estimated values;
a data summing unit configured to sum the online data, the offline data and the historical data transmitted from the online data delegation unit, the offline data delegation unit and the historical data delegation unit; and
a risk management unit configured to receive result data, acquired by summing the online data, the offline data and the historical data by the data summing unit, and to manage condition-based risk of the transformer using the result data.

2. The transformer condition-based risk management system according to claim 1, wherein each of the online data measurement unit and the offline data measurement unit includes a plurality of sensor modules to measure various pieces of condition data of the transformer, and the sensor modules include a dissolved gas analysis sensor, a bushing monitoring sensor, a temperature sensor and a load current measurement sensor so as to construct representative tables of transformers.

3. The transformer condition-based risk management system according to claim 1, wherein the online data measurement unit monitors a condition of the transformer in real time online and separates temperature and gas data from various pieces of data acquired from the transformer.

4. The transformer condition-based risk management system according to claim 1, wherein the technical issues include detection of technical defects of a specific device, manufacturer, design or part, detection of abnormality during condition diagnosis, detection of failures and failure of a diagnostic system, the economic issues include fluctuation in a price or stock level of a specific part, change in a maintenance policy or budget and fluctuation in a power supply loss of a customer, and the social issues include environmental factors, safety factors, fault tolerance and external confidence.

5. The transformer condition-based risk management system according to claim 1, wherein the online data delegation unit, the offline data delegation unit and the historical data delegation unit set the current measured values and the measured value change estimated values to be within the range of 0-2 and assign “1” to an online measured value, “2” to a measured value several months ago and a degradation estimated value and “0” to repaired/supplemented equipment as delegation values.

6. The transformer condition-based risk management system according to claim 1, wherein the risk management unit calculates condition-based risk management (CBRM) data by Equation 1 below,
$$C B R M = \frac{\sum ( S * W * D )}{\sum ( {S}_{max} * W * {D}_{2} )} , \qquad [ Equation 1 ]$$
wherein S is an online or offline measured value level, which is within the range of 0-4, 0 indicates a level of safety, 1 indicates a level of interest, 2 indicates a level of attention, 3 indicates a level of warning, 4 indicates a level of danger, W is a weight of a measured factor, which is within in the range 1-20, D is a current measured value or a measured value change estimated value, which is within the range of 0-2, 1 is assigned to an online measured value, 2 is assigned to a measured value several months ago and a degradation estimated value, and 0 is assigned to repaired/supplemented equipment.

7. A transformer condition-based risk management method comprising:
measuring real-time condition monitoring data including temperature, dissolved gas and partial discharge data from a transformer online, periodic measurement data including insulating property data from the transformer offline, and historical data reflected in design of the transformer;
assigning weights of corresponding assessment indexes out of assessment indexes according to technical, economic or social issues, to the respective measured data;
receiving weighted data and then assigning delegation values to current measured values and measured value change estimated values; and
summing respective data, acquired by assigning the delegation values, and then executing asset management through risk analysis of the transformer.

8. The transformer condition-based risk management method according to claim 7, wherein the data measured online and offline includes data regarding conditions of an insulating paper, coils, an iron core and insulating oil at the inside of the transformer, data regarding conditions of a tap changer, a bushing, a tank, a lightning arrester, a cooling pump and a cooling fan at the outside of the transformer, failure records including a record of surge invading the transformer and an accident record, and data regarding importance of the transformer according to whether or not a substation equipped with the transformer is a primary substation constituting the backbone of an electric power system or a substation for distribution.

9. The transformer condition-based risk management method according to claim 7, wherein risk of the transformer is assessed by divisionally assessing the inside of the transformer, the outside of the transformer, failure records and importance of the transformer according to the type of a substation, the inside of the transformer is assessed by assessing conditions of an insulating paper, coils, an iron core and insulating oil, the outside of the transformer is assessed by assessing conditions of a tap changer, a bushing, a tank, a lightning arrester, a cooling pump and a cooling fan, the failure records include a record of surge invading the transformer and an accident record, and the failure records are reflected in assessment of risk of the transformer.
